(19) United States
(12) Patent Application Publication
(10) Pub. No.: US 2026/0090102 A1
(43) Pub. Date: Mar. 26, 2026

(54) ACTIVE MATRIX SUBSTRATE AND DISPLAY DEVICE

(71) Applicant: Sharp Display Technology Corporation, Kameyama City (JP)

(72) Inventors: Kengo HARA, Kameyama City (JP); Tohru Daitoh, Kameyama City (JP); Hajime Imai, Kameyama City (JP); Teruyuki Ueda, Kameyama City (JP); Tatsuya Kawasaki, Kameyama City (JP)

(21) Appl. No.: 19/333,623

(22) Filed: Sep. 19, 2025

(30) Foreign Application Priority Data
Sep. 20, 2024 (JP) 2024-164214

(51) Int. Cl. H10D 86/40; G02F 1/1362; G02F 1/1368; H10D 86/60; H10K 59/121

(52) U.S. Cl. CPC H10D 86/423; G02F 1/136286; G02F 1/1368; H10D 86/60; H10K 59/1213

(57) ABSTRACT

An active matrix substrate includes a substrate and a plurality of oxide semiconductor TFTs. Each of the oxide semiconductor TFTs includes an oxide semiconductor layer including a channel region, a source contact region, and a drain contact region, a lower gate electrode, and an upper gate electrode. In a plan view, when a protrusion width of the lower gate electrode from the upper gate electrode toward the source contact region is referred to as a first protrusion width, a protrusion width of the lower gate electrode from the upper gate electrode toward the drain contact region is referred to as a second protrusion width, and a sum of the first protrusion width and the second protrusion width is referred to as a third protrusion width, the plurality of oxide semiconductor include a first TFT and a second TFT having the third protrusion widths different from each other.

### CROSS-REFERENCE TO RELATED APPLICATIONS

This application claims the benefit of priority to Japanese Patent Application Number 2024-164214 filed on Sep. 20, 2024. The entire contents of the above-identified application are hereby incorporated by reference.

### BACKGROUND

### Technical Field

The disclosure relates to an active matrix substrate and, more particularly, to an active matrix substrate including an oxide semiconductor TFT. The disclosure also relates to a display device including such an active matrix substrate.

An active matrix substrate used in a liquid crystal display device, an organic electroluminescence (EL) display device, or the like includes a display region including a plurality of pixels, and a region other than the display region (a non-display region). In the display region, a thin film transistor (hereinafter referred to as a “TFT”) as a switching element is provided for each of the pixels. As such a TFT, in the related art, a TFT including an amorphous silicon film serving as an active layer (hereinafter referred to as an “amorphous silicon TFT”) and a TFT including a polycrystalline silicon film serving as an active layer (hereinafter referred to as a “polycrystalline silicon TFT”) have been widely used.

As a material of the active layer of a TFT, it has been proposed in recent years to use an oxide semiconductor in place of amorphous silicon and polycrystalline silicon.

Such a TFT is referred to as an “oxide semiconductor TFT”.

The oxide semiconductor has a higher mobility than amorphous silicon. Thus, the oxide semiconductor TFT can operate at a higher speed than the amorphous silicon TFT.

A structure of the TFT is roughly classified into a bottom gate structure and a top gate structure. Currently, the bottom gate structure is often adopted for the oxide semiconductor TFT, but it is also proposed to use the top gate structure (see, for example, JP 2015-109315 A). In the top gate structure, the gate insulating layer can be thinned, resulting in high current supply performance. In addition, a double gate structure in which gate electrodes are respectively provided above and below the active layer has been recently proposed (for example, JP 6486174 B).

In the non-display region of the active matrix substrate, peripheral circuits including a TFT may be monolithically (integrally) formed. For example, by forming a drive circuit monolithically, the non-display region is narrowed and the mounting process is simplified, resulting in cost reduction. For example, in the non-display region, a gate drive circuit is formed monolithically. In devices such as smartphones, where there is a high demand for narrowing the frame, a demultiplexer circuit, which is also referred to as a source shared driving (SSD) circuit, may be formed monolithically.

In the present specification, a TFT disposed in each pixel of the display region (in the active matrix substrate used in an organic EL display device, a plurality of TFTs constituting a pixel circuit) is referred to as a “pixel TFT”. In addition, a TFT constituting a peripheral circuit provided in the non-display region is referred to as a “peripheral circuit TFT”.

In the active matrix substrate, from the perspective of the manufacturing process, it is preferable that the peripheral circuit TFT be also formed by using the same oxide semiconductor film as the pixel TFT and by using a common process. Thus, the peripheral circuit TFT and the pixel TFT usually have the same structure, and their TFT characteristics are also substantially the same.

### SUMMARY

However, characteristics required for the peripheral circuit TFT and the pixel TFT may be different from each other. In addition, among peripheral circuit TFTs, required characteristics may be different depending on the intended use.

Further, in the active matrix substrate used in the organic EL display device, a pixel circuit including at least two types of pixel TFTs (referred to as a “drive pixel TFT” and a “selection pixel TFT”) is provided in one pixel. The selection pixel TFT has a function of selecting a pixel by changing a voltage applied to the drive pixel TFT. The drive pixel TFT has a function of supplying a current required for light emission. The selection pixel TFT and the drive pixel TFT have different functions, and thus the characteristics required for the selection pixel TFT and the drive pixel TFT may also be different.

As described above, in an active matrix substrate provided with a plurality of TFTs having different uses, it is required to separately produce a plurality of oxide semiconductor TFTs having different characteristics so that each TFT can have the required characteristics according to the use.

An embodiment of the disclosure has been conceived in light of the above-described problems, and an object of the disclosure is to provide an active matrix substrate including a plurality of oxide semiconductor TFTs having different characteristics from one another.

The present specification discloses an active matrix substrate and a display device described in the following Items.

### [Item 1]

An active matrix substrate including
a substrate; and
a plurality of oxide semiconductor TFTs supported by the substrate,
wherein each of the plurality of oxide semiconductor TFTs includes
an oxide semiconductor layer including a channel region, and a source contact region and a drain contact region located on a respective one of both sides of the channel region,
a lower gate electrode disposed between the substrate and the oxide semiconductor layer, and
an upper gate electrode disposed on the opposite side of the lower gate electrode with respect to the oxide semiconductor layer, and
in a plan view, when a protrusion width of the lower gate electrode from the upper gate electrode toward the source contact region is referred to as a first protrusion width, a protrusion width of the lower gate electrode from the upper gate electrode toward the drain contact region is referred to as a second protrusion width, and a sum of the first protrusion width and the second protrusion width is referred to as a third protrusion width,
the plurality of oxide semiconductor TFTs include a first TFT and a second TFT having the third protrusion widths different from each other.

### [Item 2]

The active matrix substrate according to Item 1, wherein a width of the upper gate electrode of the first TFT along a channel length direction is substantially the same as a width of the upper gate electrode of the second TFT along the channel length direction.

### [Item 3]

The active matrix substrate according to Item 1 or 2, wherein the third protrusion width of the first TFT is larger than the third protrusion width of the second TFT.

### [Item 4]

The active matrix substrate according to Item 3, wherein each of the first protrusion width and the second protrusion width of the first TFT is 1 μm or more.

### [Item 5]

The active matrix substrate according to Item 3 or 4, wherein each of the first protrusion width and the second protrusion width of the first TFT is 2 μm or less.

### [Item 6]

The active matrix substrate according to any one of Items 3 to 5, wherein each of the first protrusion width and the second protrusion width of the second TFT is 0 μm or less.

### [Item 7]

The active matrix substrate according to any one of Items 3 to 6,
wherein each of the plurality of oxide semiconductor TFTs further includes
a lower gate insulating layer disposed between the lower gate electrode and the oxide semiconductor layer, and
an upper gate insulating layer disposed between the upper gate electrode and the oxide semiconductor layer, and
in a plan view, when a protrusion width of the upper gate insulating layer from the upper gate electrode toward the source contact region is referred to as a fourth protrusion width and a protrusion width of the upper gate insulating layer from the upper gate electrode toward the drain contact region is referred to as a fifth protrusion width,
each of the fourth protrusion width and the fifth protrusion width of the first TFT is 0.5 μm or less, and
each of the fourth protrusion width and the fifth protrusion width of the second TFT is 1 μm or more.

### [Item 8]

The active matrix substrate according to any one of Items 3 to 7,
wherein each of the plurality of oxide semiconductor TFTs further includes
a lower gate insulating layer disposed between the lower gate electrode and the oxide semiconductor layer, and
an upper gate insulating layer disposed between the upper gate electrode and the oxide semiconductor layer, and
when two edges of the upper gate insulating layer each located at a respective one of both ends in a channel length direction are referred to as a first edge and a second edge, respectively, and two edges of the lower gate electrode each located at a respective one of both ends in the channel length direction are referred to as a third edge and a fourth edge, respectively,
the first edge and the second edge of the upper gate insulating layer of the first TFT are located closer to the inside in the channel length direction than the third edge and the fourth edge, respectively, of the lower gate electrode of the first TFT, and
the first edge and the second edge of the upper gate insulating layer of the second TFT are located closer to the outside in the channel length direction than the third edge and the fourth edge, respectively, of the lower gate electrode of the second TFT.

### [Item 9]

The active matrix substrate according to any one of Items 3 to 8, wherein the oxide semiconductor layer of the first TFT is formed in the same layer as the oxide semiconductor layer of the second TFT.

### [Item 10]

The active matrix substrate according to any one of Items 3 to 8,
wherein the oxide semiconductor layer of the first TFT is formed in a layer different from the oxide semiconductor layer of the second TFT, and
mobility of the oxide semiconductor layer of the first TFT is higher than mobility of the oxide semiconductor layer of the second TFT.

### [Item 11]

The active matrix substrate according to any one of Items 1 to 10, wherein the plurality of oxide semiconductor TFTs include an oxide semiconductor TFT having the second protrusion width larger than the first protrusion width.

### [Item 12]

The active matrix substrate according to any one of Items 1 to 9, wherein the oxide semiconductor layer includes an In-Ga-Zn-O based semiconductor.

### [Item 13]

The active matrix substrate according to Item 10,
wherein each of the oxide semiconductor layer of the first TFT and the oxide semiconductor layer of the second TFT includes In and/or Sn, and
a sum of atomic ratios of In and Sn to all metal elements in the oxide semiconductor layer of the second TFT is smaller than a sum of atomic ratios of In and Sn to all metal elements in the oxide semiconductor layer of the first TFT.

### [Item 14]

The active matrix substrate according to Item 10,
wherein both the oxide semiconductor layer of the first TFT and the oxide semiconductor layer of the second TFT include an In-Ga-Zn-O based semiconductor, and
an atomic ratio of In to all metal elements in the second oxide semiconductor layer is smaller than an atomic ratio of In to all metal elements in the oxide semiconductor layer of the first TFT.

### [Item 15]

A display device including the active matrix substrate according to any one of Items 1 to 14.

### [Item 16]

The display device according to Item 15, wherein the display device is a liquid crystal display device.

### [Item 17]

The display device according to Item 15, wherein the display device is an organic EL display device.

According to an embodiment of the disclosure, an active matrix substrate including a plurality of oxide semiconductor TFTs having different characteristics from one another can be provided.

### BRIEF DESCRIPTION OF DRAWINGS

The disclosure will be described with reference to the accompanying drawings, wherein like numbers reference like elements.

FIG. 1 is a cross-sectional view schematically illustrating an active matrix substrate 100 according to an embodiment of the disclosure.

FIG. 2 is a plan view schematically illustrating the active matrix substrate 100.

FIG. 3 is a graph showing a relationship between a first protrusion width PW1 and a second protrusion width PW2 and a mobility μ.

FIG. 4 is a graph showing a relationship between the first protrusion width PW1 and the second protrusion width PW2 and a source-drain breakdown voltage.

FIG. 5 is a cross-sectional view illustrating an example of an oxide semiconductor TFT 10 in which the first protrusion width PW1 and the second protrusion width PW2 are different from each other.

FIG. 6A is a process cross-sectional view for explaining a manufacturing method of the active matrix substrate 100.

FIG. 6B is a process cross-sectional view for explaining the manufacturing method of the active matrix substrate 100.

FIG. 6C is a process cross-sectional view for explaining the manufacturing method of the active matrix substrate 100.

FIG. 6D is a process cross-sectional view for explaining the manufacturing method of the active matrix substrate 100.

FIG. 6E is a process cross-sectional view for explaining the manufacturing method of the active matrix substrate 100.

FIG. 6F is a process cross-sectional view for explaining the manufacturing method of the active matrix substrate 100.

FIG. 6G is a process cross-sectional view for explaining the manufacturing method of the active matrix substrate 100.

FIG. 6H is a process cross-sectional view for explaining the manufacturing method of the active matrix substrate 100.

FIG. 7 is a cross-sectional view schematically illustrating the active matrix substrate 100.

FIG. 8 is a cross-sectional view schematically illustrating an active matrix substrate 200 according to an embodiment of the disclosure.

FIG. 9 is a plan view schematically illustrating the active matrix substrate 200.

FIG. 10A is a process cross-sectional view for explaining a manufacturing method of the active matrix substrate 200.

FIG. 10B is a process cross-sectional view for explaining the manufacturing method of the active matrix substrate 200.

FIG. 10C is a process cross-sectional view for explaining the manufacturing method of the active matrix substrate 200.

FIG. 10D is a process cross-sectional view for explaining the manufacturing method of the active matrix substrate 200.

FIG. 10E is a process cross-sectional view for explaining the manufacturing method of the active matrix substrate 200.

FIG. 10F is a process cross-sectional view for explaining the manufacturing method of the active matrix substrate 200.

FIG. 10G is a process cross-sectional view for explaining the manufacturing method of the active matrix substrate 200.

FIG. 10H is a process cross-sectional view for explaining the manufacturing method of the active matrix substrate 200.

FIG. 10I is a process cross-sectional view for explaining the manufacturing method of the active matrix substrate 200.

FIG. 10J is a process cross-sectional view for explaining the manufacturing method of the active matrix substrate 200.

FIG. 11 is a cross-sectional view schematically illustrating the active matrix substrate 200.

FIG. 12 is a schematic plan view schematically illustrating an active matrix substrate 301 for a liquid crystal display device.

FIG. 13 is a schematic plan view schematically illustrating an active matrix substrate 302 for an organic EL display device.

FIG. 14 is a diagram illustrating an example of a pixel circuit PC of the active matrix substrate 302.

### DESCRIPTION OF EMBODIMENTS

TFTs provided in an active matrix substrate may have different required characteristics depending on respective uses. Examples of suitable TFT characteristics will be described below. Note that the uses and required characteristics of the TFTs are not limited to the examples described below.

As described above, in the active matrix substrate used in an organic EL display device, a pixel circuit including at least a drive pixel TFT and a selection pixel TFT is provided in one pixel. From the perspective of current control and the perspective of suitably performing multi-gray scale display, it is preferable that the Vg-Id (Vg represents a gate voltage and Id represents a drain current) characteristic of the drive pixel TFT be gentle (that is, not steep) to some extent. On the other hand, the selection pixel TFT preferably has high mobility (i.e., a large ON-current).

For peripheral circuit TFTs as well, characteristics required for the TFTs are different depending on intended uses and functions. For example, among the peripheral circuit TFTs, a TFT used in a demultiplexer circuit (hereinafter, a “DMX circuit TFT”) and some TFTs constituting a drive circuit (e.g., an output transistor) are required to have high mobility because a relatively large ON-current needs to be flown therein.

In addition, a high source-drain breakdown voltage is required for a TFT to which a relatively high voltage is applied among the TFTs included in the active matrix substrate.

As described above, the TFTs included in the active matrix substrate have different required characteristics depending on respective uses. As a result of conducting detailed studies, the inventor of the present application has found that electrical characteristics of the TFT can be controlled and adjusted by changing a relative positional relationship between an upper gate electrode and a lower gate electrode in the oxide semiconductor TFT having a double gate structure, and has arrived at the disclosure of the present application. Hereinafter, an embodiment of the disclosure will be described with reference to the drawings, but the disclosure is not limited to the embodiment described below.

### First Embodiment

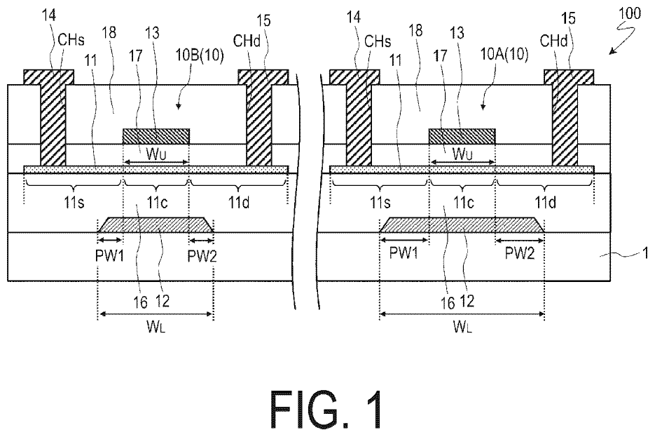

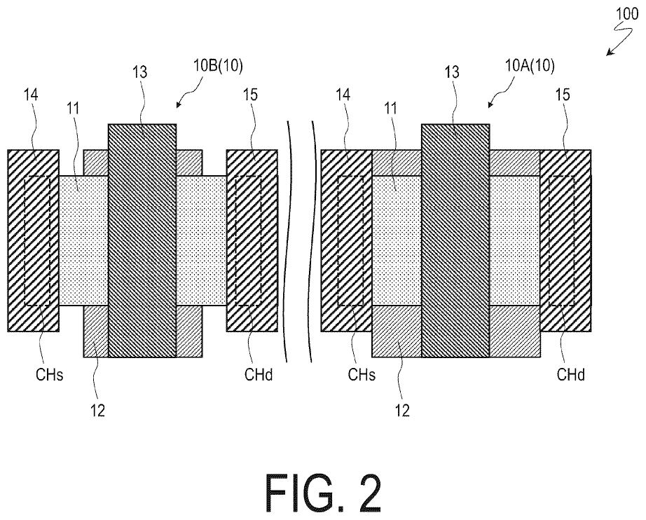

An active matrix substrate 100 according to the present embodiment will be described with reference to FIGS. 1 and 2. FIGS. 1 and 2 are a cross-sectional view and a plan view, respectively, schematically illustrating the active matrix substrate 100.

As illustrated in FIG. 1 and FIG. 2, the active matrix substrate 100 includes a substrate 1 and a plurality of oxide semiconductor TFTs 10 supported by the substrate 1. In FIGS. 1 and 2, a certain oxide semiconductor TFT (hereinafter referred to as a “first TFT”) 10A of the plurality of oxide semiconductor TFTs 10 is illustrated on the right side, and another certain oxide semiconductor TFT (hereinafter referred to as a “second TFT”) 10B of the plurality of oxide semiconductor TFTs 10 is illustrated on the left side.

Each oxide semiconductor TFT 10 includes an oxide semiconductor layer 11, a lower gate electrode 12, an upper gate electrode 13, a source electrode 14, and a drain electrode 15. Each oxide semiconductor TFT 10 further includes a lower gate insulating layer 16 and an upper gate insulating layer 17.

The oxide semiconductor layer 11 includes a channel region 11c, and a source contact region 11s and a drain contact region 11d that are respectively located on both sides of the channel region 11c. The source contact region 11s and the drain contact region 11d are low-resistive regions having specific resistance lower than that of the channel region 11c. Such a low-resistive region can be formed by, for example, subjecting the oxide semiconductor layer 11 to resistance reduction processing using the upper gate electrode 13 as a mask.

The lower gate electrode 12 is disposed between the substrate 1 and the oxide semiconductor layer 11. That is, the lower gate electrode 12 is located below the oxide semiconductor layer 11.

The lower gate insulating layer 16 is provided so as to cover the lower gate electrode 12, and is disposed between the lower gate electrode 12 and the oxide semiconductor layer 11. The lower gate electrode 12 faces the channel region 11c of the oxide semiconductor layer 11 via the lower gate insulating layer 16.

The upper gate electrode 13 is disposed on the opposite side of the lower gate electrode 12 with respect to the oxide semiconductor layer 11. That is, the upper gate electrode 13 is located above the oxide semiconductor layer 11.

The upper gate insulating layer 17 is disposed between the upper gate electrode 13 and the oxide semiconductor layer 11. The upper gate electrode 13 faces the channel region 11c of the oxide semiconductor layer 11 via the upper gate insulating layer 17.

The source electrode 14 is electrically connected to the source contact region 11s of the oxide semiconductor layer 11. The drain electrode 15 is electrically connected to the drain contact region 11d of the oxide semiconductor layer 11.

In the illustrated example, an interlayer insulating layer 18 is provided so as to cover the oxide semiconductor layer 11, the upper gate insulating layer 17, and the upper gate electrode 13, and the source electrode 14 and the drain electrode 15 are disposed on the interlayer insulating layer 18.

A source contact hole CHs exposing the source contact region 11s of the oxide semiconductor layer 11 and a drain contact hole CHd exposing the drain contact region 11d of the oxide semiconductor layer 11 are formed in the interlayer insulating layer 18 and the upper gate insulating layer 17. The source electrode 14 is connected to the source contact region 11s in the source contact hole CHs. The drain electrode 15 is connected to the drain contact region 11d in the drain contact hole CHd.

In the illustrated example, in both the first TFT 10A and the second TFT 10B, a width W_{L} of the lower gate electrode 12 along a channel length direction is larger than a width W_{U} of the upper gate electrode 13 along the channel length direction. In addition, in both the first TFT 10A and the second TFT 10B, the lower gate electrode 12 protrudes from the upper gate electrode 13 to both sides (a source contact region 11s side and a drain contact region 11d side) in a plan view.

Hereinafter, a protrusion width PW1 of the lower gate electrode 12 from the upper gate electrode 13 toward the source contact region 11s is referred to as a “first protrusion width”, and a protrusion width PW2 of the lower gate electrode 12 from the upper gate electrode 13 toward the drain contact region 11d is referred to as a “second protrusion width”. The sum of the first protrusion width PW1 and the second protrusion width PW2 (i.e., PW1+PW2) is referred to as a “third protrusion width”.

In the present embodiment, the third protrusion width of the first TFT 10A and the third protrusion width of the second TFT 10B are different from each other. Hereinafter, a more specific description of this point will be made.

As illustrated in FIGS. 1 and 2, in the present embodiment, the width W_{L} of the lower gate electrode 12 of the first TFT 10A is larger than the width W_{L} of the lower gate electrode 12 of the second TFT 10B. On the other hand, the width W_{U} of the upper gate electrode 13 of the first TFT 10A and the width W_{U} of the upper gate electrode 13 of the second TFT 10B are substantially the same. Thus, the third protrusion width of the first TFT 10A is larger than the third protrusion width of the second TFT 10B. More specifically, the first protrusion width PW1 of the first TFT 10A is larger than the first protrusion width PW1 of the second TFT 10B, and the second protrusion width PW2 of the first TFT 10A is larger than the second protrusion width PW2 of the second TFT 10B.

As a result of conducting detailed studies on the structure and characteristics of the oxide semiconductor TFT having the double gate structure, the inventor of the present application has found that the mobility of the oxide semiconductor TFT can be controlled and adjusted by changing the protrusion width (the first protrusion width, the second protrusion width, and the third protrusion width described above) of the lower gate electrode. Specifically, the inventor has found that the mobility can be increased by making the third protrusion width large. In the illustrated example, the third protrusion width of the first TFT 10A is larger than the third protrusion width of the second TFT 10B, and thus the mobility of the first TFT 10A can be made higher than the mobility of the second TFT 10B.

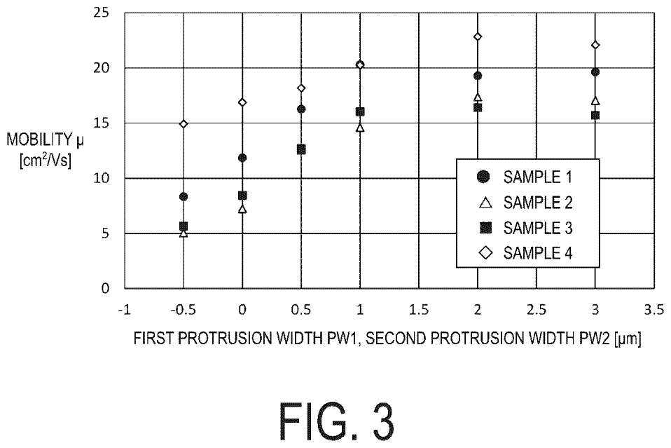

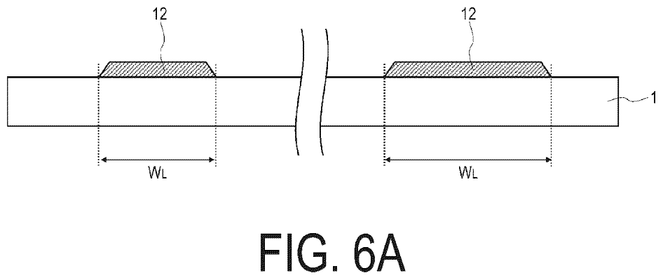

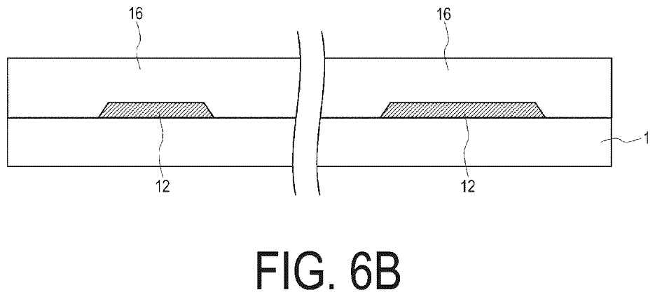

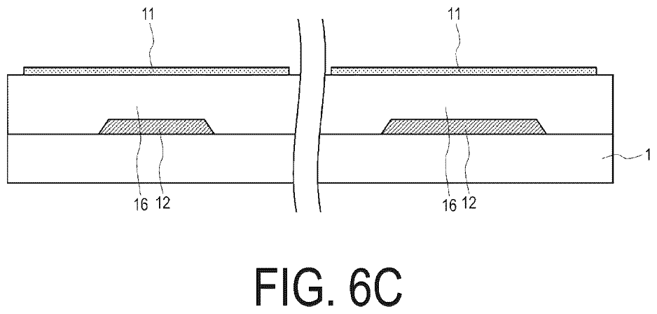

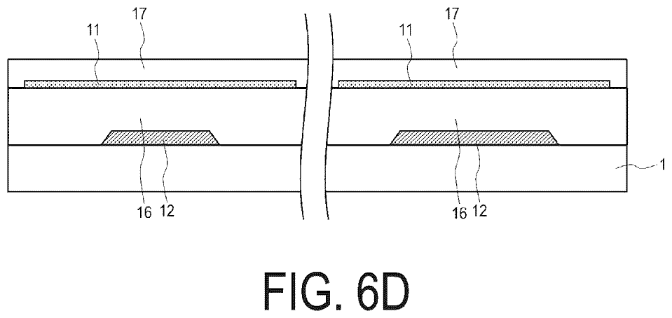

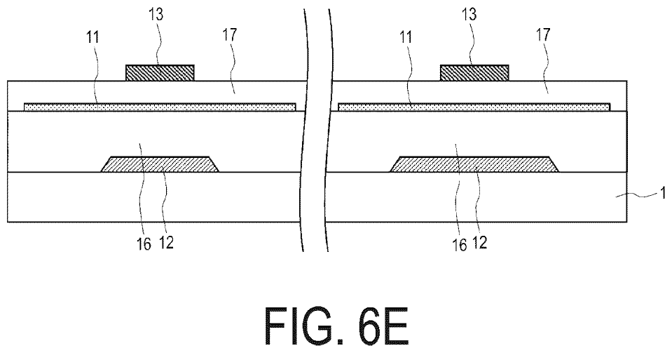

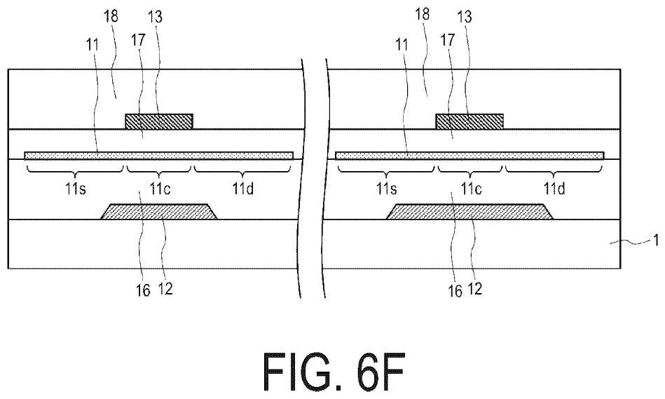

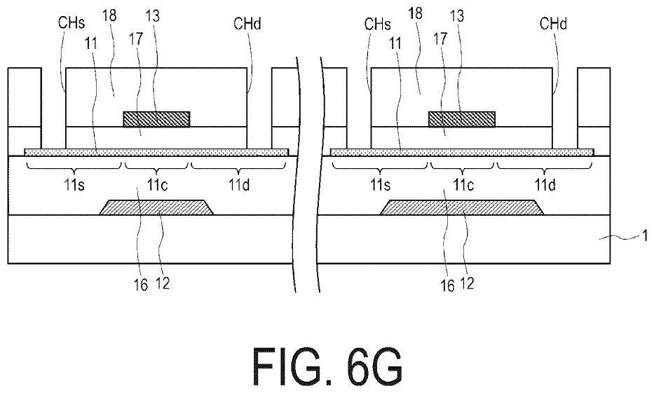

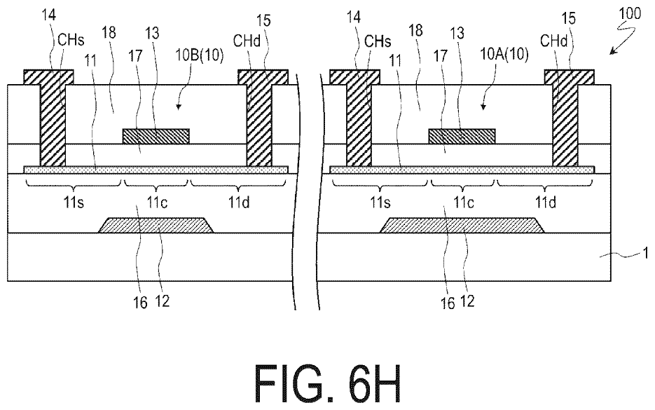

FIG. 3 shows results of verifying an influence on the mobility μ by changing the first protrusion width PW1 and the second protrusion width PW2 (while maintaining a relationship PW1=PW2) for four oxide semiconductor TFTs (Sample 1 to Sample 4) that were actually fabricated. Sample 1 to Sample 4 were prepared in the same manner as the manufacturing method described later with reference to FIG. 6A to FIG. 6H. The specifications of Sample 1 and Sample 4 are slightly different from those of Sample 2 and Sample 3, and this will be described later.

It can be seen from FIG. 3 that the mobility μ increases as the first protrusion width PW1 and the second protrusion width PW2 increase (i.e., as the third protrusion width increases). As described above, it was confirmed that the mobility of the oxide semiconductor TFT 10 can be controlled and adjusted by changing the protrusion widths (the first protrusion width PW1, the second protrusion width PW2, and the third protrusion width) of the lower gate electrode 12.

It can also be seen from FIG. 3 that the effect of increasing the mobility μ is high when the first protrusion width PW1 and the second protrusion width PW2 are 1 μm or more. Thus, from the perspective of increasing the mobility of the first TFT 10A, each of the first protrusion width PW1 and the second protrusion width PW2 of the first TFT 10A is preferably 1 μm or more.

Further, it can be seen from FIG. 3 that the effect of improving the mobility is substantially saturated when the first protrusion width PW1 and the second protrusion width PW2 exceed 2 μm. When the first protrusion width PW1 and the second protrusion width PW2 are too large, a leakage current may occur between the lower gate electrode 12 and the source electrode 14 or between the lower gate electrode 12 and the drain electrode 15 when a pinhole is formed in the oxide semiconductor layer 11. Thus, from the perspective of ensuring reliability, each of the first protrusion width PW1 and the second protrusion width PW2 of the first TFT 10A is preferably 2 μm or less.

As can be seen from the fact that data are plotted in a case in which the first protrusion width PW1 and the second protrusion width PW2 are −0.5 μm in FIG. 3, the first protrusion width PW1 and the second protrusion width PW2 can each have a negative value.

The first protrusion width PW1 has a negative value when the upper gate electrode 13 protrudes from the lower gate electrode 12 toward the source contact region 11s in a plan view. In this case, the first protrusion width PW1 is obtained by reversing the positive and negative values of the protrusion width of the upper gate electrode 13 from the lower gate electrode 12 toward the source contact region 11s. For example, when the upper gate electrode 13 protrudes from the lower gate electrode 12 toward the source contact region 11s by 0.5 μm, the first protrusion width PW1 is −0.5 μm.

Similarly, the second protrusion width PW2 has a negative value when the upper gate electrode 13 protrudes from the lower gate electrode 12 toward the drain contact region 11d in a plan view. In this case, the second protrusion width PW2 is obtained by reversing the positive and negative values of the protrusion width of the upper gate electrode 13 from the lower gate electrode 12 toward the drain contact region 11d. For example, when the upper gate electrode 13 protrudes from the lower gate electrode 12 toward the drain contact region 11d by 0.5 μm, the second protrusion width PW2 is −0.5 μm.

Although FIGS. 1 and 2 illustrate the case in which the first protrusion width PW1 and the second protrusion width PW2 of the second TFT 10B are positive values, each of the first protrusion width PW1 and the second protrusion width PW2 of the second TFT 10B (the oxide semiconductor TFT 10 having a relatively low mobility) may be 0 μm or less.

As described above, the mobility of the oxide semiconductor TFT 10 can be controlled and adjusted by changing the protrusion widths (the first protrusion width PW1, the second protrusion width PW2, and the third protrusion width) of the lower gate electrode 12. Further, according to the study by the inventor of the present application, it has been found that the source-drain breakdown voltage of the oxide semiconductor TFT 10 can be increased by making the protrusion width of the lower gate electrode 12 large.

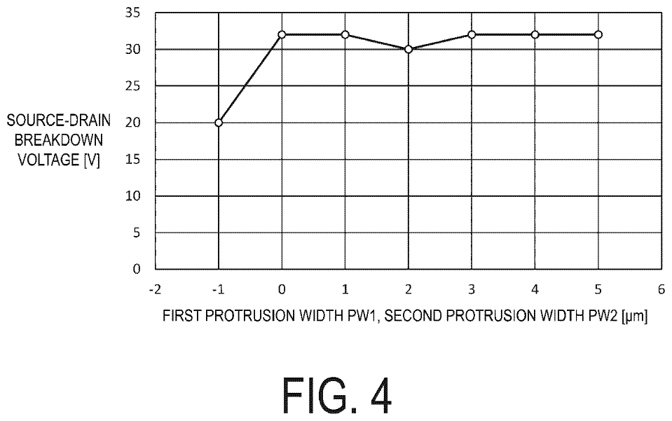

FIG. 4 shows results of verifying an influence on the source-drain breakdown voltage by changing the first protrusion width PW1 and the second protrusion width PW2 (while maintaining a relationship PW1=PW2) for Sample 3. It can be seen from FIG. 4 that the source-drain breakdown voltage is reduced when the first protrusion width PW1 and the second protrusion width PW2 are less than 0 μm. Thus, from the perspective of ensuring the source-drain breakdown voltage, each of the first protrusion width PW2 and the second protrusion width PW1 of the oxide semiconductor TFT 10 to which a relatively high source-drain voltage is applied is preferably 0 μm or more.

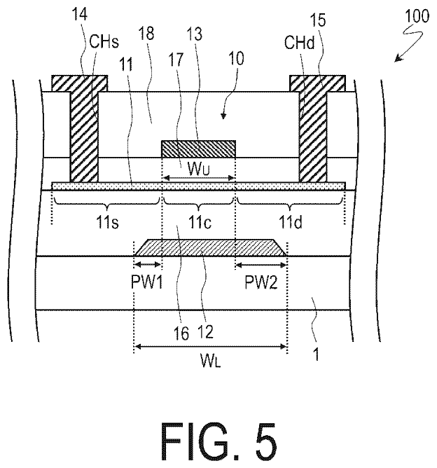

When attention is focused on one oxide semiconductor TFT 10, the first protrusion width PW1 and the second protrusion width PW2 thereof may be the same or different from each other. FIG. 5 illustrates an example of the oxide semiconductor TFT 10 in which the first protrusion width PW1 and the second protrusion width PW2 are different from each other. In the example illustrated in FIG. 5, the second protrusion width PW2 is larger than the first protrusion width PW1.

When a large source-drain voltage is applied to the TFT and dielectric breakdown occurs, the semiconductor layer is damaged more on the drain side (that is, the drain contact region) than on the source side (that is, the source contact region). When it is difficult to increase both the first protrusion width PW1 and the second protrusion width PW2 due to layout constraints, dielectric breakdown of the oxide semiconductor TFT 10 can be prevented and reliability can be improved by making the second protrusion width PW2 larger than the first protrusion width PW1 as illustrated in FIG. 5.

Here, a manufacturing method of the active matrix substrate 100 will be described with reference to FIG. 6A to FIG. 6H. FIGS. 6A to 6H are process cross-sectional views for explaining the manufacturing method of the active matrix substrate 100.

First, as illustrated in FIG. 6A, the lower gate electrode 12 is formed on the substrate 1. Specifically, the lower gate electrode 12 can be formed by forming a lower gate conductive film (thickness of, for example, 50 nm or more and 500 nm or less) on the substrate 1 having insulating properties by a sputtering method or the like, and then patterning the lower gate conductive film. At this time, the lower gate electrodes 12 are formed so that the width W_{L} of the lower gate electrode 12 for the first TFT 10A (illustrated on the right side in FIG. 6A) is larger than the width W_{L} of the lower gate electrode 12 for the second TFT 10B (illustrated on the left side in FIG. 6A).

A glass substrate, a plastic substrate (resin substrate) having heat resistance, or the like can be used as the substrate 1, for example.

As the lower gate conductive film, for example, a metal film including an element selected from aluminum (Al), chromium (Cr), copper (Cu), tantalum (Ta), titanium (Ti), molybdenum (Mo), or tungsten (W), or an alloy film including these elements as components can be used. In addition, a layered film including a plurality of films among these films may be used. Here, as the lower gate conductive film, a metal film or an alloy film containing Cu or Al is used.

Subsequently, as illustrated in FIG. 6B, the lower gate insulating layer 16 that covers the lower gate electrode 12 is formed. The lower gate insulating layer 16 is formed by CVD, for example. A thickness of the lower gate insulating layer 16 is, for example, 200 nm or more and 600 nm or less.

As the lower gate insulating layer 16, a silicon oxide (SiO₂) layer, a silicon nitride (SiNx) layer, a silicon oxynitride (SiOxNy; x>y) layer, a silicon nitride oxide (SiNxOy; x>y) layer, or the like can be used as appropriate. The lower gate insulating layer 16 may have a layered structure. For example, a silicon nitride layer, a silicon nitride oxide layer, or the like may be formed on the substrate 1 side (lower layer) in order to prevent diffusion of impurities and the like from the substrate 1, and a silicon oxide layer, a silicon oxynitride layer, or the like may be formed on a layer (upper layer) on top of the substrate 1 side layer in order to ensure insulating properties.

Subsequently, as illustrated in FIG. 6C, the oxide semiconductor layer 11 is formed on the lower gate insulating layer 16. Specifically, first, the oxide semiconductor layer 11 can be formed by depositing an oxide semiconductor film by using a sputtering method and then patterning the oxide semiconductor film. Here, as the oxide semiconductor film, an In-Ga-Zn-O based semiconductor film is used. The patterning of the oxide semiconductor film can be performed by, for example, wet etching using a PAN-based etching solution containing phosphoric acid, nitric acid, and acetic acid, or an oxalic acid-based etching solution.

Subsequently, as illustrated in FIG. 6D, the upper gate insulating layer 17 is formed so as to cover the lower gate insulating layer 16 and the oxide semiconductor layer 11. The upper gate insulating layer 17 is formed by, for example, CVD. As the upper gate insulating layer 17, for example, an insulating layer similar to the lower gate insulating layer 16 (illustrated as the lower gate insulating layer 16) can be used. Here, as the upper gate insulating layer 17, a silicon oxide layer is formed. When an oxide layer such as the silicon oxide layer is used as the upper gate insulating layer 17, oxygen deficiencies generated in the channel region 11c of the oxide semiconductor layer 11 can be reduced by the oxide layer, so that a decrease in resistance of the channel region 11c can be suppressed. The thickness of the upper gate insulating layer 17 is, for example, 50 nm or more and 200 nm or less.

Next, as illustrated in FIG. 6E, the upper gate electrode 13 is formed on the upper gate insulating layer 17. Specifically, the upper gate electrode 13 can be formed by forming an upper gate conductive film (thickness of, for example, 50 nm or more and 500 nm or less) on the upper gate insulating layer 17 by a sputtering method or the like, and then patterning the upper gate conductive film. As the upper gate conductive film, a conductive film similar to the lower gate conductive film can be used.

Thereafter, the resistance reduction processing may be performed on the oxide semiconductor layer 11. The resistance reduction processing is, for example, plasma processing. By the resistance reduction processing, a region of the oxide semiconductor layer 11 not overlapping the upper gate electrode 13 is a low resistance region (the source contact region 11s and the drain contact region 11d) having a lower specific resistance than a region (the channel region 11c) overlapping the upper gate electrode 13. Note that the method of the resistance reduction processing is not limited to the processing exemplified here.

Subsequently, as illustrated in FIG. 6F, the interlayer insulating layer 18 that covers the upper gate insulating layer 17 and the upper gate electrode 13 is formed. The interlayer insulating layer 18 can be formed by, for example, CVD. As the interlayer insulating layer 18, an inorganic insulating layer such as a silicon oxide (SiO₂) layer, a silicon nitride (SiNx) layer, a silicon oxynitride (SiOxNy; x>y) layer, or a silicon nitride oxide (SiNxOy; x>y) layer can be used in a single layer or in layers. A thickness of the interlayer insulating layer 18 is, for example, 200 nm or more and 700 nm or less. Here, as the interlayer insulating layer 18, a silicon oxide layer is used.

Subsequently, as illustrated in FIG. 6G, the source contact hole CHs and the drain contact hole CHd are formed in the interlayer insulating layer 18 and the upper gate insulating layer 17. The source contact hole CHs and the drain contact hole CHd can be formed by, in particular, the photolithography process and the etching. The etching may be dry etching, for example.

Subsequently, as illustrated in FIG. 6H, the source electrode 14 is formed on the interlayer insulating layer 18 and in the source contact hole CHs, and the drain electrode 15 is formed on the interlayer insulating layer 18 and in the drain contact hole CHd. Specifically, the source electrode 14 and the drain electrode 15 can be formed by forming a source conductive film (thickness of, for example, 50 nm or more and 500 nm or less) on the interlayer insulating layer 18, in the source contact hole CHs, and in the drain contact hole CHd, and then patterning the source conductive film. The patterning of the source conductive film can be performed, for example, by dry etching or wet etching. As the source conductive film, an element selected from aluminum (Al), chromium (Cr), copper (Cu), tantalum (Ta), titanium (Ti), molybdenum (Mo), and tungsten (W), or an alloy including these elements as components can be used, for example. For example, the source conductive film may have a triple-layer structure of titanium film-aluminum film-titanium film, or a triple-layer structure of molybdenum film-aluminum film-molybdenum film. Note that the source conductive film is not limited to the triple-layer structure, and may have a single-layer structure, a dual-layer structure, or a layered structure of four or more layers. Here, a layered film having a lower layer of a Ti film (thickness of 15 nm or more and 70 nm or less) and an upper layer of a Cu film (thickness of 200 nm or more and 400 nm or less) is used.

In this manner, the active matrix substrate 100 including the first TFT 10A and the second TFT 10B is obtained.

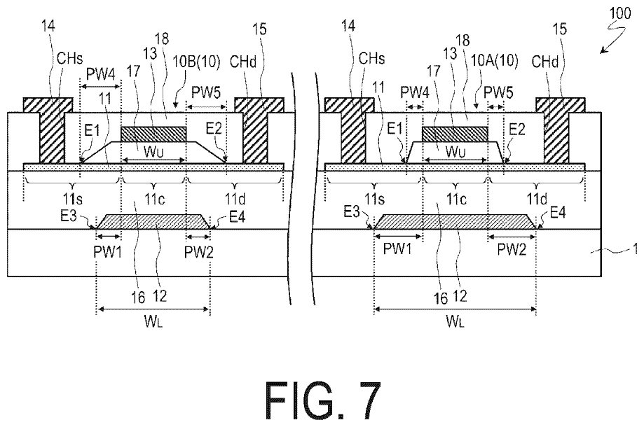

Although FIG. 1 and the like illustrate a configuration in which the upper gate insulating layer 17 covers not only the channel region 11c of the oxide semiconductor layer 11 but also the source contact region 11s and the drain contact region 11d (more strictly, a portion of the source contact region 11s, the portion not overlapping the source contact hole CHs and a portion of the drain contact region 11d, the portion not overlapping the drain contact hole CHd), embodiments of the disclosure are not limited to such a configuration, and a configuration illustrated in FIG. 7 may be adopted. In the configuration illustrated in FIG. 7, the upper gate insulating layer 17 is patterned so as not to cover at least partially the source contact region 11s and the drain contact region 11d (more strictly, a portion of the source contact region 11s, the portion not overlapping the source contact hole CHs and a portion of the drain contact region 11d, the portion not overlapping the drain contact hole CHd).

In the configuration illustrated in FIG. 7, the upper gate insulating layer 17 slightly protrudes from the upper gate electrode 13 toward the source contact region 11s and the drain contact region 11d in a plan view. Hereinafter, a protrusion width PW4 of the upper gate insulating layer 17 from the upper gate electrode 13 toward the source contact region 11s is referred to as a “fourth protrusion width”, and a protrusion width PW5 of the upper gate insulating layer 17 from the upper gate electrode 13 toward the drain contact region 11d is referred to as a “fifth protrusion width”.

In the configuration illustrated in FIG. 7, the fourth protrusion width PW4 of the first TFT 10A is smaller than the fourth protrusion width PW4 of the second TFT 10B, and the fifth protrusion width PW5 of the first TFT 10A is smaller than the fifth protrusion width PW5 of the second TFT 10B. When two edges E1 and E2 of the upper gate insulating layer 17 each located at a respective one of both ends in the channel length direction are referred to as a “first edge” and a “second edge”, respectively, and two edges E3 and E4 of the lower gate electrode 12 each located at a respective one of both ends in the channel length direction are referred to as a “third edge” and a “fourth edge”, respectively, the first edge E1 and the second edge E2 of the upper gate insulating layer 17 of the first TFT 10A are located closer to the inside in the channel length direction than the third edge E3 and the fourth edge E4, respectively, of the lower gate electrode 12 of the first TFT 10A. In contrast, the first edge E1 and the second edge E2 of the upper gate insulating layer 17 of the second TFT 10B are located closer to the outside in the channel length direction than the third edge E3 and the fourth edge E4, respectively, of the lower gate electrode 12 of the second TFT 10B.

According to the study by the inventor of the present application, it has been found that the fourth protrusion width PW4 and the fifth protrusion width PW5 described above can also affect the mobility of the oxide semiconductor TFT 10. Specifically, from the perspective of increasing the mobility, the fourth protrusion width PW4 and the fifth protrusion width PW5 are preferably small, and the mobility can be increased when the first edge E1 and the second edge E2 of the upper gate insulating layer 17 are located closer to the inside in the channel length direction than the third edge E3 and the fourth edge E4, respectively, of the lower gate electrode 12. Thus, in a case in which the mobility of the first TFT 10A is made higher than the mobility of the second TFT 10B, as illustrated in FIG. 7, it is preferable that the fourth protrusion width PW4 of the first TFT 10A is smaller than the fourth protrusion width PW4 of the second TFT 10B, and the fifth protrusion width PW5 of the first TFT 10A is smaller than the fifth protrusion width PW5 of the second TFT 10B. Further, it is preferable that the first edge E1 and the second edge E2 of the upper gate insulating layer 17 of the first TFT 10A are located closer to the inside in the channel length direction than the third edge E3 and the fourth edge E4, respectively, of the lower gate electrode 12 of the first TFT 10A. On the other hand, the first edge E1 and the second edge E2 of the upper gate insulating layer 17 of the second TFT 10B may be located closer to the outside in the channel length direction than the third edge E3 and the fourth edge E4, respectively, of the lower gate electrode 12 of the second TFT 10B.

Sample 1 to Sample 4 whose verification results are shown in FIG. 3 have the configuration illustrated in FIG. 7, and the fourth protrusion width PW4 and the fifth protrusion width PW5 of Sample 1 and Sample 4 are smaller than the fourth protrusion width PW4 and the fifth protrusion width PW5, respectively, of Sample 2 and Sample 3. It can be seen from FIG. 3 that the mobilities of Sample 1 and Sample 4 are higher than the mobilities of Sample 2 and Sample 3.

From the perspective of increasing the mobility of the first TFT 10A, each of the fourth protrusion width PW4 and the fifth protrusion width PW5 of the first TFT 10A is preferably, for example, 0.5 μm or less. Each of the fourth protrusion width PW4 and the fifth protrusion width PW5 of the second TFT 10B may be 1 μm or more.

### Second Embodiment

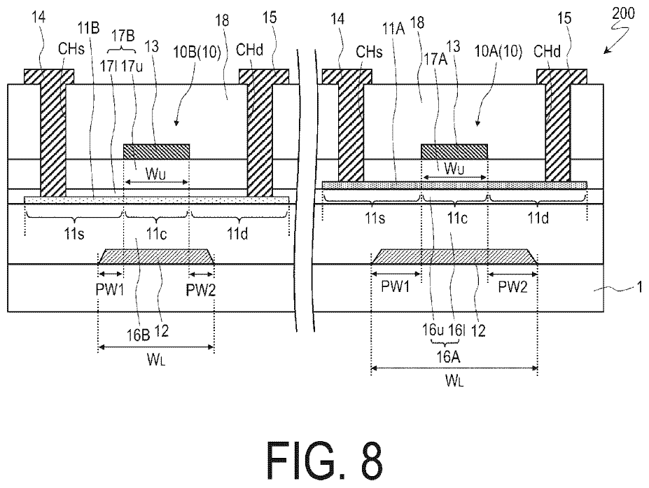

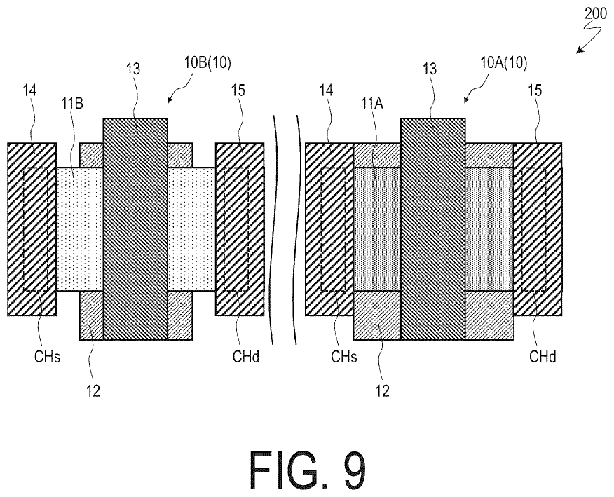

An active matrix substrate 200 according to the present embodiment will be described with reference to FIGS. 8 and 9. FIGS. 8 and 9 are a cross-sectional view and a plan view, respectively, schematically illustrating the active matrix substrate 200. In the following, description will focus on points where the active matrix substrate 200 differs from the active matrix substrate 100 according to the first embodiment.

In the active matrix substrate 100 of the first embodiment, the oxide semiconductor layer 11 of the first TFT 10A is formed in the same layer as the oxide semiconductor layer 11 of the second TFT 10B (that is, from the same oxide semiconductor film in the same process). In contrast, in the active matrix substrate 200 of the present embodiment, an oxide semiconductor layer 11A of the first TFT 10A is formed in a layer different from an oxide semiconductor layer 11B of the second TFT 10B (that is, from a different oxide semiconductor film in a different process). The mobility of the oxide semiconductor layer 11A of the first TFT 10A is higher than the mobility of the oxide semiconductor layer 11B of the second TFT 10B.

A lower gate insulating layer 16A of the first TFT 10A has a layered structure including a lower layer 16l and an upper layer 16u disposed on the lower layer 16l. A lower gate insulating layer 16B of the second TFT 10B is formed in the same layer as the lower layer 16l of the lower gate insulating layer 16A.

An upper gate insulating layer 17B of the second TFT 10B has a layered structure including a lower layer 17l and an upper layer 17u disposed on the lower layer 17l. The lower layer 17l of the upper gate insulating layer 17B is formed in the same layer as the upper layer 16u of the lower gate insulating layer 16A. An upper gate insulating layer 17A of the first TFT 10A is formed in the same layer as the upper layer 17u of the upper gate insulating layer 17B.

Also, in the active matrix substrate 200 of the present embodiment, the first protrusion width PW1 of the first TFT 10A is larger than the first protrusion width PW1 of the second TFT 10B, and the second protrusion width PW2 of the first TFT 10A is larger than the second protrusion width PW2 of the second TFT 10B. Thus, the third protrusion width of the first TFT 10A is larger than the third protrusion width of the second TFT 10B. Thus, the mobility of the first TFT 10A can be made higher than the mobility of the second TFT 10B.

In the active matrix substrate 200 of the present embodiment, the oxide semiconductor layer 11A of the first TFT 10A is formed in a layer different from the oxide semiconductor layer 11B of the second TFT 10B, and the mobility of the oxide semiconductor layer 11A of the first TFT 10A is higher than the mobility of the oxide semiconductor layer 11B of the second TFT 10B. Thus, the difference between the mobility of the first TFT 10A and the mobility of the second TFT 10B can be further increased.

The compositions, crystal structures, thicknesses, forming methods, and the like of the oxide semiconductor layers 11A and 11B are not particularly limited.

The compositions of the oxide semiconductor layers 11A and 11B may be different from each other. Here, “compositions are different” means that each of the layers contains different types of metal elements or metal elements with different composition ratios. For example, each of the oxide semiconductor layers 11A and 11B may contain In and/or Sn, and a sum of atomic ratios of In and Sn to all metal elements in the oxide semiconductor layer 11B may be smaller than a sum of atomic ratios of In and Sn to all metal elements in the oxide semiconductor layer 11A.

Alternatively, each of the oxide semiconductor layers 11A and 11B may be an In-Ga-Zn-O based oxide semiconductor layer, and an atomic ratio of In in the oxide semiconductor layer 11B may be smaller than an atomic ratio of In in the oxide semiconductor layer 11A. In this case, in one of the oxide semiconductor layers 11A and 11B, the atomic ratio of In to all metal elements and an atomic ratio of Zn to all metal elements may be the same.

Further, the oxide semiconductor layer 11A may contain Sn, and the oxide semiconductor layer 11B need not contain Sn. Alternatively, the oxide semiconductor layer 11B may contain Sn at a lower concentration of Sn than a concentration of Sn in the oxide semiconductor layer 11A. In other words, an atomic ratio of Sn to all metal elements in the oxide semiconductor layer 11B may be smaller than an atomic ratio of Sn to all metal elements in the oxide semiconductor layer 11A.

As the oxide semiconductor layer 11B, for example, an In-Ga-Zn-O based semiconductor layer (e.g., In:Ga:Zn=1:1:1) can be used. As the oxide semiconductor layer 11A, for example, an In-Ga-Zn-O based semiconductor layer (for example, In:Ga:Zn=3:1:2), an In-Sn-Zn-O based semiconductor layer, an In-Al-Sn-Zn-O based semiconductor layer, an In-W-Zn-O based semiconductor layer, an In-Sn-O based semiconductor layer, an In-Zn-O based semiconductor layer, an In-Ga-Sn-O based semiconductor layer, an In-Sn-Ti-Zn-O based semiconductor layer, or the like can be used.

Further, the oxide semiconductor layers 11A and 11B may have different crystal structures from each other. For example, one of the oxide semiconductor layers 11A and 11B may be an amorphous oxide semiconductor layer, and the other may be a crystalline oxide semiconductor layer containing a crystalline portion.

Even when the ratio of each metal element of the oxide semiconductor layer 11A and the ratio of each metal element of the oxide semiconductor layer 11B are the same, the mobilities of these oxide semiconductor layers can be made different from each other by changing the film formation method or the film formation conditions. For example, when forming an oxide semiconductor layer having each of the same metal element ratios as the oxide semiconductor layers 11A and 11B by sputtering, the atmosphere in the chamber (for example, the flow ratio of oxygen and Ar supplied to the chamber) may be different between these oxide semiconductor films. Specifically, when forming the oxide semiconductor film 11B, a flow ratio of oxygen to Ar may be set great (for example, 80%), and when forming the oxide semiconductor layer 11A, the flow ratio of oxygen to Ar may be set smaller than when forming the oxide semiconductor layer 11B (for example, 20%). As a result, the mobility of the oxide semiconductor layer 11B can be made higher than the mobility of the oxide semiconductor layer 11A.

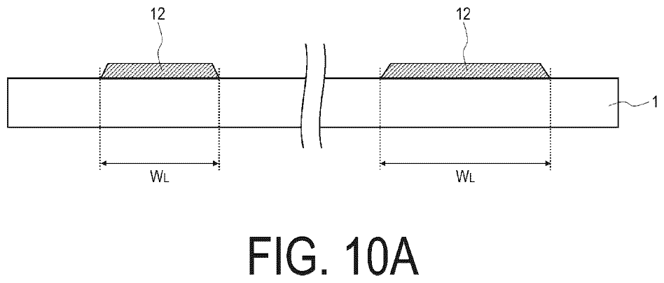

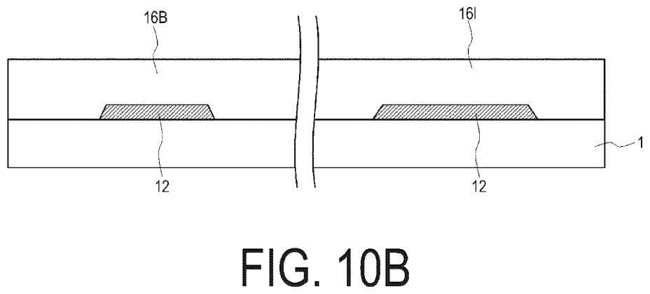

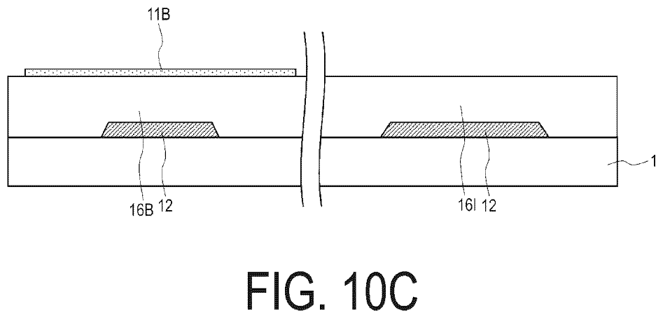

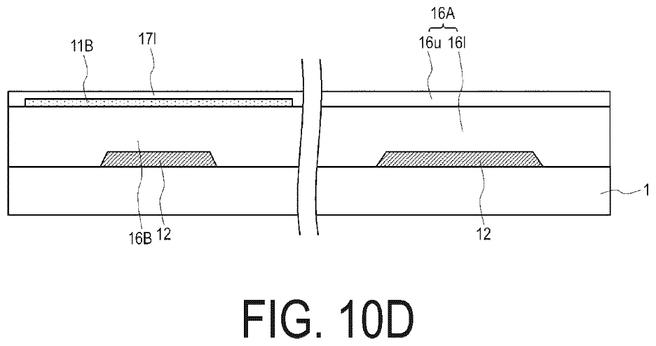

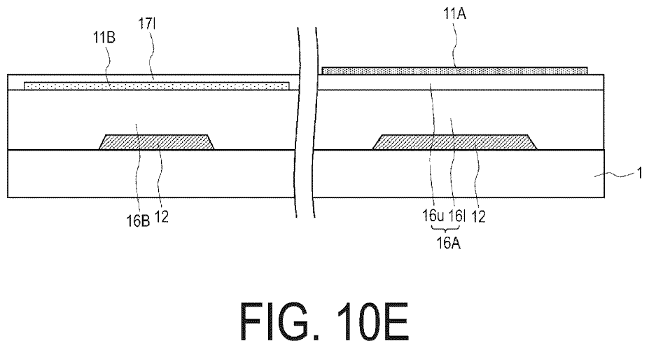

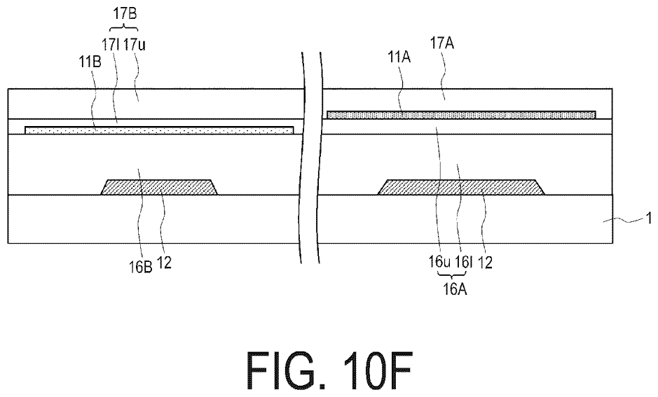

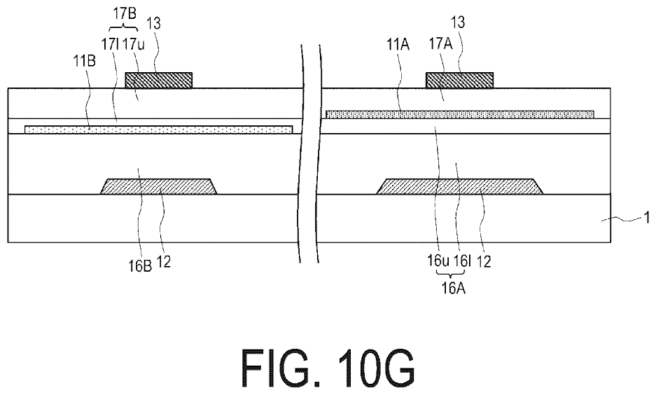

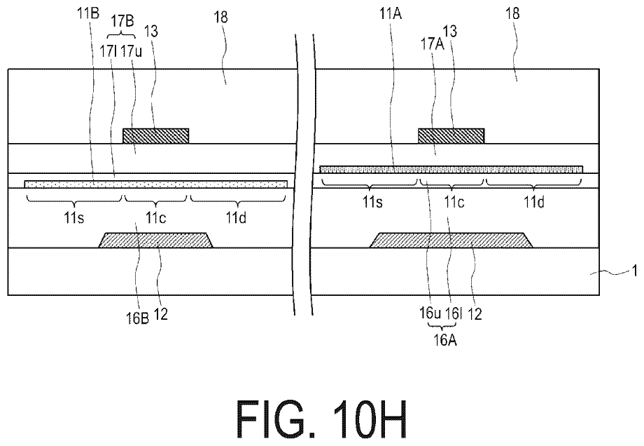

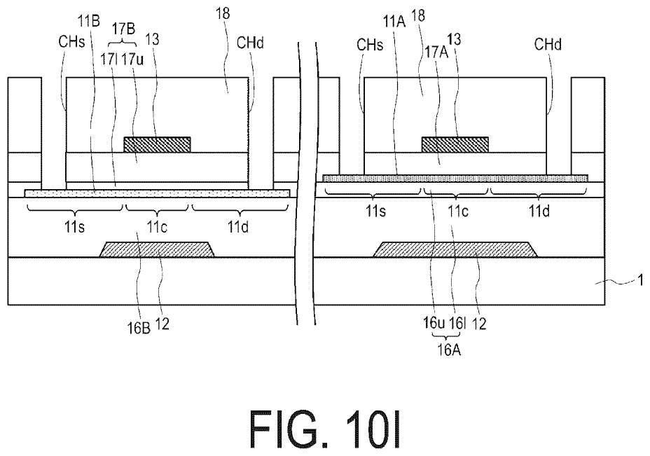

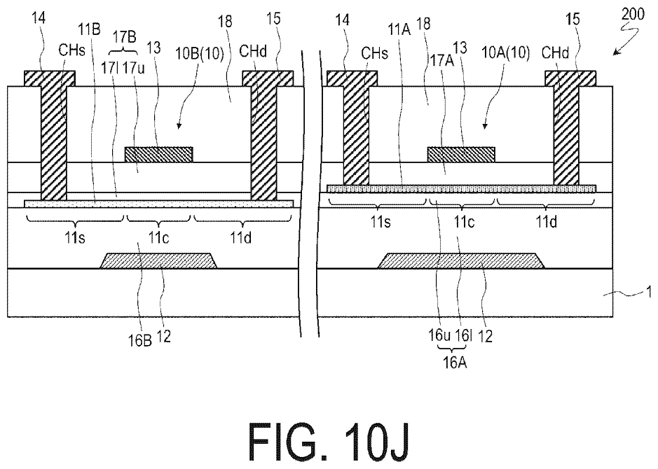

Here, a manufacturing method of the active matrix substrate 200 will be described with reference to FIG. 10A to FIG. 10J. FIGS. 10A to 10J are process cross-sectional views for explaining the manufacturing method of the active matrix substrate 200.

First, as illustrated in FIG. 10A, the lower gate electrode 12 is formed on the substrate 1. Specifically, the lower gate electrode 12 can be formed by forming a lower gate conductive film on the substrate 1 having insulating properties by a sputtering method or the like, and then patterning the lower gate conductive film. At this time, the lower gate electrodes 12 are formed so that the width W_{L} of the lower gate electrode 12 for the first TFT 10A (illustrated on the right side in FIG. 10A) is larger than the width W_{L} of the lower gate electrode 12 for the second TFT 10B (illustrated on the left side in FIG. 10A). As the lower gate conductive film, a conductive film similar to the lower gate conductive film (illustrated as the lower gate conductive film) in the first embodiment can be used.

Subsequently, as illustrated in FIG. 10B, the lower layer 16l of the lower gate insulating layer 16A and the lower gate insulating layer 16B are formed by, for example, CVD. As the lower layer 16l of the lower gate insulating layer 16A and the lower gate insulating layer 16B, an insulating layer similar to the lower gate insulating layer 16 (illustrated as the lower gate insulating layer 16) in the first embodiment can be used.

Subsequently, as illustrated in FIG. 10C, the oxide semiconductor layer 11B is formed on the lower gate insulating layer 16B. Specifically, first, the oxide semiconductor layer 11B can be formed by depositing an oxide semiconductor film by using a sputtering method and then patterning the oxide semiconductor film. Here, as the oxide semiconductor film, an In-Ga-Zn-O based semiconductor film (In:Ga:Zn=1:1:1) is used.

Subsequently, as illustrated in FIG. 10D, the upper layer 16u of the lower gate insulating layer 16A and the lower layer 17l of the upper gate insulating layer 17B are formed by, for example, CVD. Here, as the upper layer 16u of the lower gate insulating layer 16A and the lower layer 17l of the upper gate insulating layer 17B, a silicon oxide layer is formed.

Subsequently, as illustrated in FIG. 10E, the oxide semiconductor layer 11A is formed on the lower gate insulating layer 16A. Specifically, first, the oxide semiconductor layer 11A can be formed by depositing an oxide semiconductor film by using a sputtering method and then patterning the oxide semiconductor film. Here, as the oxide semiconductor film for the oxide semiconductor layer 11A, an In-Ga-Zn-O based semiconductor film is used. As can be seen from the above description, for example, by setting the atomic ratio of In in the oxide semiconductor layer 11A to be larger than the atomic ratio of In in the oxide semiconductor layer 11B, the mobility of the oxide semiconductor layer 11A can be made higher than the mobility of the oxide semiconductor layer 11B (that is, the mobility of the oxide semiconductor layer 11B can be made lower than the mobility of the oxide semiconductor layer 11A).

Subsequently, as illustrated in FIG. 10F, the upper gate insulating layer 17A and the upper layer 17u of the upper gate insulating layer 17B are formed by, for example, CVD. Here, as the upper gate insulating layer 17A and the upper layer 17u of the upper gate insulating layer 17B, a silicon oxide layer is formed.

Subsequently, as illustrated in FIG. 10G, the upper gate electrode 13 is formed on the upper gate insulating layers 17A and 17B. Specifically, the upper gate electrode 13 can be formed by forming an upper gate conductive film on the upper gate insulating layer 17 by a sputtering method or the like, and then patterning the upper gate conductive film. As the upper gate conductive film, a conductive film similar to the lower gate conductive film can be used. Thereafter, the resistance reduction processing may be performed on the oxide semiconductor layers 11A and 11B.

Subsequently, as illustrated in FIG. 10H, the interlayer insulating layer 18 that covers the upper gate insulating layers 17A and 17B and the upper gate electrode 13 is formed. The interlayer insulating layer 18 can be formed by, for example, CVD. Here, as the interlayer insulating layer 18, a silicon oxide layer is used.

Subsequently, as illustrated in FIG. 10I, the source contact hole CHs and the drain contact hole CHd are formed in the interlayer insulating layer 18 and the upper gate insulating layers 17A and 17B. The source contact hole CHs and the drain contact hole CHd can be formed by, in particular, the photolithography process and the etching. The etching may be dry etching, for example.

Subsequently, as illustrated in FIG. 10J, the source electrode 14 is formed on the interlayer insulating layer 18 and in the source contact hole CHs, and the drain electrode 15 is formed on the interlayer insulating layer 18 and in the drain contact hole CHd. Specifically, the source electrode 14 and the drain electrode 15 can be formed by forming a source conductive film on the interlayer insulating layer 18, in the source contact hole CHs, and in the drain contact hole CHd, and then patterning the source conductive film. As the source conductive film, a conductive film similar to the source conductive film (illustrated as the source conductive film) in the first embodiment can be used.

In this manner, the active matrix substrate 200 including the first TFT 10A and the second TFT 10B is obtained.

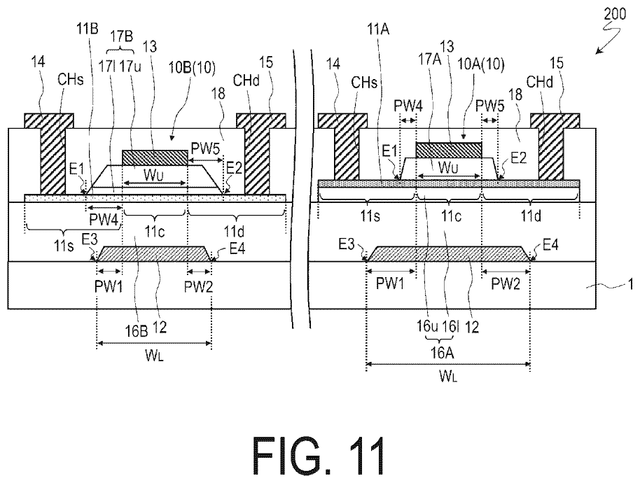

Although FIG. 8 and the like illustrate a configuration in which the upper gate insulating layers 17A and 17B cover not only the channel region 11c of the oxide semiconductor layers 11A and 11B but also the source contact region 11s and the drain contact region 11d (more strictly, a portion of the source contact region 11s, the portion not overlapping the source contact hole CHs and a portion of the drain contact region 11d, the portion not overlapping the drain contact hole CHd), embodiments of the disclosure are not limited to such a configuration, and a configuration illustrated in FIG. 11 may be adopted. In the configuration illustrated in FIG. 11, the upper gate insulating layers 17A and 17B are patterned so as not to at least partially cover the source contact region 11s and the drain contact region 11d (more strictly, a portion of the source contact region 11s, the portion not overlapping the source contact hole CHs and a portion of the drain contact region 11d, the portion not overlapping the drain contact hole CHd).

In the configuration illustrated in FIG. 11, the upper gate insulating layers 17A and 17B slightly protrude from the upper gate electrode 13 toward the source contact region 11s and the drain contact region 11d in a plan view. The fourth protrusion width PW4 of the first TFT 10A is smaller than the fourth protrusion width PW4 of the second TFT 10B, and the fifth protrusion width PW5 of the first TFT 10A is smaller than the fifth protrusion width PW5 of the second TFT 10B. Further, the first edge E1 and the second edge E2 of the upper gate insulating layer 17A of the first TFT 10A are located closer to the inside in the channel length direction than the third edge E3 and the fourth edge E4, respectively, of the lower gate electrode 12 of the first TFT 10A. In contrast, it is preferable that the first edge E1 and the second edge E2 of the upper gate insulating layer 17B of the second TFT 10B are located closer to the outside in the channel length direction than the third edge E3 and the fourth edge E4, respectively, of the lower gate electrode 12 of the second TFT 10B.

From the perspective of increasing the mobility, the fourth protrusion width PW4 and the fifth protrusion width PW5 are preferably small, and the mobility can be increased when the first edge E1 and the second edge E2 of the upper gate insulating layer are located closer to the inside in the channel length direction than the third edge E3 and the fourth edge E4, respectively, of the lower gate electrode 12. Thus, in a case in which the mobility of the first TFT 10A is made higher than the mobility of the second TFT 10B, as illustrated in FIG. 11, it is preferable that the fourth protrusion width PW4 of the first TFT 10A is smaller than the fourth protrusion width PW4 of the second TFT 10B, and the fifth protrusion width PW5 of the first TFT 10A is smaller than the fifth protrusion width PW5 of the second TFT 10B. Further, it is preferable that the first edge E1 and the second edge E2 of the upper gate insulating layer 17A of the first TFT 10A are located closer to the inside in the channel length direction than the third edge E3 and the fourth edge E4, respectively, of the lower gate electrode 12 of the first TFT 10A. On the other hand, the first edge E1 and the second edge E2 of the upper gate insulating layer 17B of the second TFT 10B may be located closer to the outside in the channel length direction than the third edge E3 and the fourth edge E4, respectively, of the lower gate electrode 12 of the second TFT 10B.

From the perspective of increasing the mobility of the first TFT 10A, each of the fourth protrusion width PW4 and the fifth protrusion width PW5 of the first TFT 10A is preferably, for example, 0.5 μm or less. Each of the fourth protrusion width PW4 and the fifth protrusion width PW5 of the second TFT 10B may be 1 μm or more.

### Structure of Active Matrix Substrate for Liquid Crystal Display Device

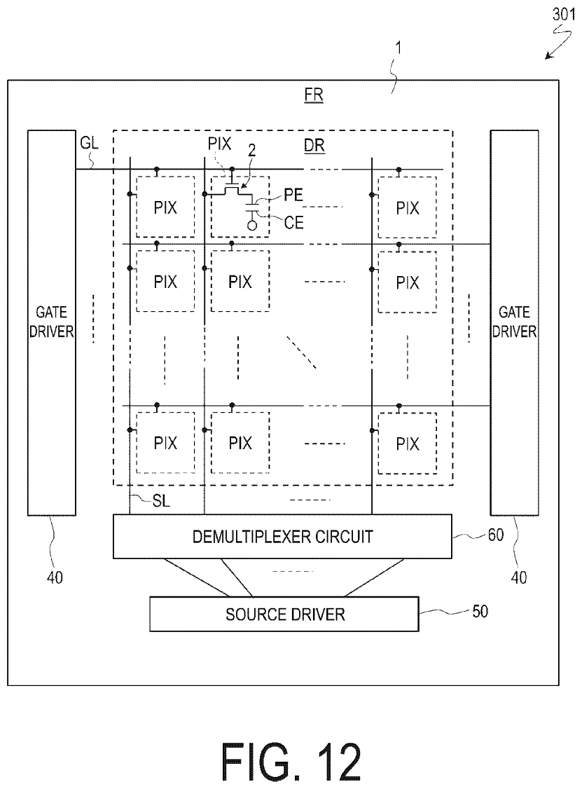

A structure of an active matrix substrate 301 for a liquid crystal display device will be described with reference to FIG. 12. FIG. 12 is a schematic plan view schematically illustrating the active matrix substrate 301.

The active matrix substrate 301 includes a display region DR and a non-display region (also referred to as a “peripheral region” or a “frame region”) FR as illustrated in FIG. 12. The display region DR is defined by a plurality of pixel regions PIXs. The plurality of pixel regions PIXs are arrayed in a matrix shape including a plurality of rows and a plurality of columns. The non-display region FR is a region positioned in a periphery of the display region DR and does not contribute to display.

In the display region DR, a plurality of gate bus lines (gate signal lines) GLs extending in a row direction, and a plurality of source bus lines (source signal lines) SLs extending in a column direction are provided. A gate bus line GL and a source bus line SL are supported by the substrate 1.

In FIG. 12, an equivalent circuit of the pixel region PIX is illustrated in the pixel region PIX in the first row and the second column. A pixel TFT 2 and a pixel electrode PE are disposed in each pixel region PIX. The pixel TFT 2 is supplied with a scanning signal (gate signal) from the corresponding gate bus line GL, and is supplied with an image signal (source signal) from the corresponding source bus line SL. The pixel TFT 2 is an oxide semiconductor TFT including an oxide semiconductor layer as an active layer. The pixel electrode PE is electrically connected to the pixel TFT 2. The equivalent circuit in FIG. 12 also illustrates a common electrode CE. The common electrode CE may be provided on the active matrix substrate 301 side or may be provided on a counter substrate (color filter substrate) side.

The active matrix substrate 301 includes a gate driver (gate drive circuit) 40 for driving the gate bus line GL and a source driver (source drive circuit) 50 for driving the source bus line SL. In the example illustrated in FIG. 12, the active matrix substrate 301 further includes a demultiplexer circuit 60. The gate driver 40, the source driver 50, and the demultiplexer circuit 60 are disposed in the non-display region FR. The gate driver 40, the source driver 50, and the demultiplexer circuit 60 are each integrally (monolithically) formed on the active matrix substrate 301 or mounted on the active matrix substrate 301. For example, the gate driver 40 and the demultiplexer circuit 60 are monolithically formed on the active matrix substrate 301, and the source driver 50 is mounted on the active matrix substrate 301. The gate driver 40 monolithically formed on the active matrix substrate 301 may be referred to as a “GDM circuit”.

A plurality of peripheral circuit TFTs constituting a peripheral circuit (the gate driver 40 or the like described above) are formed in the non-display region FR of the active matrix substrate 301.

As described above, the active matrix substrate 301 includes a plurality of the pixels TFT2 in the display region DR and the plurality of peripheral circuits TFT in the non-display region FR. Each of these TFTs may have the same structure as that of any of the first TFT 10A and the second TFT 10B illustrated in the first and second embodiments, depending on the required characteristics. For example, the peripheral circuit TFT included in the GDM circuit is required to have high mobility, and thus preferably has the same structure as the first TFT 10A. On the other hand, the pixel TFT 2 does not require as high mobility as the peripheral circuit TFT of the GDM circuit, and thus may have the same structure as the second TFT 10B.

The active matrix substrate 301 is suitably used for the liquid crystal display devices. The liquid crystal display device including the active matrix substrate 301 further includes a counter substrate (color filter substrate) disposed to face the active matrix substrate 301 and a liquid crystal layer provided between the active matrix substrate 301 and the counter substrate.

### Structure of Active Matrix Substrate for Organic EL Display Device

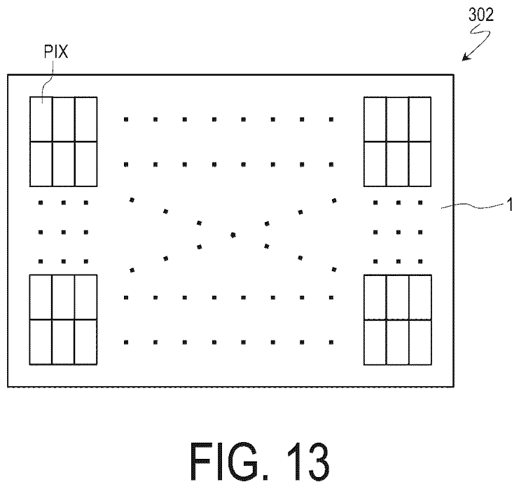

A structure of an active matrix substrate 302 for an organic EL display device will be described with reference to FIG. 13. FIG. 13 is a schematic plan view schematically illustrating the active matrix substrate 302.

The active matrix substrate 302 includes a plurality of pixel regions PIXs arrayed in a matrix shape. The active matrix substrate 302 differs from the active matrix substrate 301 for the liquid crystal display device in that each pixel region PIX includes two or more pixel TFTs.

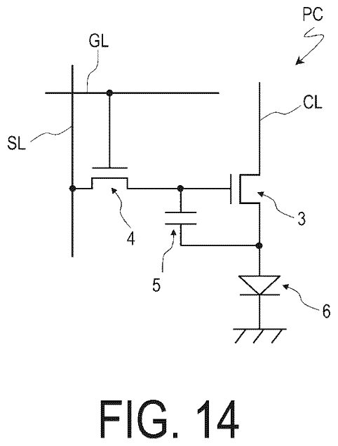

FIG. 14 illustrates an example of a pixel circuit PC provided in each pixel region PIX of the active matrix substrate 302. The pixel circuit PC illustrated in FIG. 14 includes a drive pixel TFT 3, a selection pixel TFT 4, and a capacitance element (holding capacitor) 5.

A gate electrode of the selection pixel TFT 4 is connected to the gate bus line GL. A source electrode of the selection pixel TFT 4 is connected to the source bus line SL. A drain electrode of the selection pixel TFT 4 is connected to a gate electrode of the drive pixel TFT 3 and the capacitance element 5. A source electrode of the drive pixel TFT 3 is connected to a current supply line CL. A drain electrode of the drive pixel TFT 3 is connected to an organic light emitting diode (OLED) 6 formed on the active matrix substrate 302.

When an ON signal is supplied from the gate bus line GL to the gate electrode of the selection pixel TFT 4, the selection pixel TFT 4 is brought into an ON state, and thus a signal voltage from the source bus line SL (corresponding to desired light emission luminance of the OLED 6) is applied to the capacitance element 5 and the gate electrode of the drive pixel TFT 3 via the selection pixel TFT 4. When the drive pixel TFT 3 is brought into the ON state by the signal voltage, a current from the current supply line CL flows through the drive pixel TFT 3 to the OLED 6, and then the OLED 6 emits light.

According to the embodiment of the disclosure, a plurality of oxide semiconductor TFTs (here, the drive pixel TFT 3 and the selection pixel TFT 4) having different required characteristics can be produced separately in such a pixel circuit PC. From the perspective of current control and in order to suitably perform multi-gray scale display, it is preferable that the Vg-Id (Vg represents a gate voltage and Id represents a drain current) characteristic of the drive pixel TFT 3 be gentle (that is, not steep) to some extent. On the other hand, the selection pixel TFT 4 preferably has high mobility (i.e., a large ON-current). Thus, it is preferable to adopt the same structure as the first TFT 10A described above for the selection pixel TFT 4 and adopt the same structure as the second TFT 10B described above for the drive pixel TFT 3.

Note that the pixel circuit PC is not limited to the configuration illustrated in FIG. 12. The pixel circuit PC may include three or more TFTs.

The active matrix substrate 300 may include the GDM circuit. In this case, among the peripheral circuit TFTs included in the GDM circuit, the same structure as the first TFT 10A may be adopted for the peripheral circuit TFT requiring high mobility, and the same structure as the second TFT 10B may be adopted for the peripheral circuit TFT having a Vg-Id characteristic that is preferably gentle from the perspective of current control.

The active matrix substrate 302 is suitably used for the organic EL display device.

### Oxide Semiconductor

An oxide semiconductor (also referred to as a metal oxide, or an oxide material) included in the oxide semiconductor layer of the oxide semiconductor TFT may be an amorphous oxide semiconductor or a crystalline oxide semiconductor including a crystalline portion. Examples of the crystalline oxide semiconductor include a polycrystalline oxide semiconductor, a microcrystalline oxide semiconductor, and a crystalline oxide semiconductor having a c-axis oriented substantially perpendicular to the layer surface.

Materials, structures, and film formation methods of an amorphous oxide semiconductor and the above-described crystalline oxide semiconductors, a configuration of an oxide semiconductor layer having a layered structure, and the like are described in, for example, JP 2014-007399 A. The entire contents of the disclosure of JP 2014-007399 A are incorporated in the present specification by reference.

The oxide semiconductor layer may include, for example, at least one metal element selected from In, Ga, and Zn. In the present embodiment, the oxide semiconductor layer includes, for example, an In-Ga-Zn-O-based semiconductor (for example, an indium gallium zinc oxide). Here, the In-Ga-Zn-O based semiconductor is a ternary oxide of In (indium), Ga (gallium), and Zn (zinc), there is no particular limitation on a ratio (composition ratio) of In, Ga, and Zn, and examples of the ratio include In:Ga:Zn=2:2:1, In:Ga:Zn=1:1:1, In:Ga:Zn=1:1:2, and the like. Such an oxide semiconductor layer can be formed of an oxide semiconductor film containing an In-Ga-Zn-O-based semiconductor.

The In-Ga-Zn-O-based semiconductor may be an amorphous semiconductor or may be a crystalline semiconductor. A crystalline In-Ga-Zn-O based semiconductor in which a c-axis is oriented substantially perpendicular to a layer surface is preferable as the crystalline In-Ga-Zn-O based semiconductor.

Note that a crystal structure of the crystalline In-Ga-Zn-O-based semiconductor is disclosed, for example, in JP 2014-007399 A described above, JP 2012-134475 A, JP 2014-209727 A, and the like. The entire contents of the disclosures of JP 2012-134475 A and JP 2014-209727 A are incorporated in the present specification by reference. A TFT including an In-Ga-Zn-O based semiconductor layer has high mobility (more than 20 times as compared to an a-Si TFT) and a low leakage current (less than 1/100 as compared to the a-Si TFT). Thus, such a TFT can be suitably used as a drive TFT (for example, a TFT included in a drive circuit provided in a periphery of a display region including a plurality of pixels, and on the same substrate as the display region) and a pixel TFT (TFT provided in a pixel).

In place of the In-Ga-Zn-O-based semiconductor, the oxide semiconductor layer may contain another oxide semiconductor. There may be included, for example, an In-Sn-Zn-O based semiconductor (for example, In₂O₃-SnO₂-ZnO; InSnZnO). The In-Sn-Zn-O based semiconductor is a ternary oxide of In (indium), Sn (tin), and Zn (zinc). Alternatively, the oxide semiconductor layer may include an In-Al-Zn-O-based semiconductor, an In-Al-Sn-Zn-O-based semiconductor, a Zn-O-based semiconductor, an In-Zn-O-based semiconductor, a Zn-Ti-O-based semiconductor, a Cd-Ge-O-based semiconductor, a Cd-Pb-O-based semiconductor, cadmium oxide (CdO), a Mg-Zn-O-based semiconductor, an In-Ga-Sn-O-based semiconductor, an In-Ga-O-based semiconductor, a Zr-In-Zn-O-based semiconductor, a Hf-In-Zn-O-based semiconductor, an Al-Ga-Zn-O-based semiconductor, a Ga-Zn-O-based semiconductor, an In-Ga-Zn-Sn-O-based semiconductor, an In-W-Zn-O-based semiconductor, and the like.

### INDUSTRIAL APPLICABILITY

According to an embodiment of the disclosure, an active matrix substrate including a plurality of oxide semiconductor TFTs having different characteristics from one another can be provided. The active matrix substrate according to the embodiment of the disclosure is suitably used for display devices such as a liquid crystal display device, an organic EL display device, or the like.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. An active matrix substrate comprising:
a substrate; and
a plurality of oxide semiconductor TFTs supported by the substrate,
wherein each of the plurality of oxide semiconductor TFTs includes
an oxide semiconductor layer including a channel region, and a source contact region and a drain contact region located on a respective one of both sides of the channel region,
a lower gate electrode disposed between the substrate and the oxide semiconductor layer, and
an upper gate electrode disposed on the opposite side of the lower gate electrode with respect to the oxide semiconductor layer, and
in a plan view, when a protrusion width of the lower gate electrode from the upper gate electrode toward the source contact region is referred to as a first protrusion width, a protrusion width of the lower gate electrode from the upper gate electrode toward the drain contact region is referred to as a second protrusion width, and a sum of the first protrusion width and the second protrusion width is referred to as a third protrusion width,
the plurality of oxide semiconductor TFTs include a first TFT and a second TFT having the third protrusion widths different from each other.

2. The active matrix substrate according to claim 1,
wherein a width of the upper gate electrode of the first TFT along a channel length direction is substantially the same as a width of the upper gate electrode of the second TFT along the channel length direction.

3. The active matrix substrate according to claim 1,
wherein the third protrusion width of the first TFT is larger than the third protrusion width of the second TFT.

4. The active matrix substrate according to claim 3,
wherein each of the first protrusion width and the second protrusion width of the first TFT is 1 μm or more.

5. The active matrix substrate according to claim 3,
wherein each of the first protrusion width and the second protrusion width of the first TFT is 2 μm or less.

6. The active matrix substrate according to claim 3,
wherein each of the first protrusion width and the second protrusion width of the second TFT is 0 μm or less.

7. The active matrix substrate according to claim 3,
wherein each of the plurality of oxide semiconductor TFTs further includes
a lower gate insulating layer disposed between the lower gate electrode and the oxide semiconductor layer, and
an upper gate insulating layer disposed between the upper gate electrode and the oxide semiconductor layer, and
in a plan view, when a protrusion width of the upper gate insulating layer from the upper gate electrode toward the source contact region is referred to as a fourth protrusion width and a protrusion width of the upper gate insulating layer from the upper gate electrode toward the drain contact region is referred to as a fifth protrusion width,
each of the fourth protrusion width and the fifth protrusion width of the first TFT is 0.5μm or less, and
each of the fourth protrusion width and the fifth protrusion width of the second TFT is 1μm or more.

8. The active matrix substrate according to claim 3,
wherein each of the plurality of oxide semiconductor TFTs further includes
a lower gate insulating layer disposed between the lower gate electrode and the oxide semiconductor layer, and
an upper gate insulating layer disposed between the upper gate electrode and the oxide semiconductor layer, and
when two edges of the upper gate insulating layer each located at a respective one of both ends in a channel length direction are referred to as a first edge and a second edge, respectively, and two edges of the lower gate electrode each located at a respective one of both ends in the channel length direction are referred to as a third edge and a fourth edge, respectively,
the first edge and the second edge of the upper gate insulating layer of the first TFT are located closer to the inside in the channel length direction than the third edge and the fourth edge, respectively, of the lower gate electrode of the first TFT, and
the first edge and the second edge of the upper gate insulating layer of the second TFT are located closer to the outside in the channel length direction than the third edge and the fourth edge, respectively, of the lower gate electrode of the second TFT.

9. The active matrix substrate according to claim 3,
wherein the oxide semiconductor layer of the first TFT is formed in the same layer as the oxide semiconductor layer of the second TFT.

10. The active matrix substrate according to claim 3,
wherein the oxide semiconductor layer of the first TFT is formed in a layer different from the oxide semiconductor layer of the second TFT, and
mobility of the oxide semiconductor layer of the first TFT is higher than mobility of the oxide semiconductor layer of the second TFT.

11. The active matrix substrate according to claim 1,
wherein the plurality of oxide semiconductor TFTs include an oxide semiconductor TFT having the second protrusion width larger than the first protrusion width.

12. The active matrix substrate according to claim 1,
wherein the oxide semiconductor layer includes an In-Ga-Zn-O based semiconductor.

13. The active matrix substrate according to claim 10,
wherein each of the oxide semiconductor layer of the first TFT and the oxide semiconductor layer of the second TFT includes In and/or Sn, and
a sum of atomic ratios of In and Sn to all metal elements in the oxide semiconductor layer of the second TFT is smaller than a sum of atomic ratios of In and Sn to all metal elements in the oxide semiconductor layer of the first TFT.

14. The active matrix substrate according to claim 10,
wherein both the oxide semiconductor layer of the first TFT and the oxide semiconductor layer of the second TFT include an In-Ga-Zn-O based semiconductor, and
an atomic ratio of In to all metal elements in the second oxide semiconductor layer is smaller than an atomic ratio of In to all metal elements in the oxide semiconductor layer of the first TFT.

15. A display device comprising:
the active matrix substrate according to claim 1.

16. The display device according to claim 15,
wherein the display device is a liquid crystal display device.

17. The display device according to claim 15,
wherein the display device is an organic EL display device.
